(19) United States
(12) Patent Application Publication
(10) Pub. No.: US 2006/0220093 A1
(43) Pub. Date: Oct. 5, 2006

(54) Non-volatile memory cell and method of fabrication

(75) Inventors: Robertus Theodorus Franciscus Van Schaijk, Leuven (BE); Michiel Jos Van Duuren, Leuven (BE)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: Koninklijke Philips Electronics N.V., BA Eindhoven (NL)

(21) Appl. No.: 10/539,250

(22) PCT Filed: Nov. 27, 2003
(86) PCT No.: PCT/IB03/05502

§ 371 Date: Jun. 15, 2005

(30) Foreign Application Priority Data
Dec. 19, 2002 (EP) 02080428.2

(51) Int. Cl. H01L 29/788

(52) U.S. Cl. 257/315

(57) ABSTRACT

Semiconductor device comprising a vertical split gate non-volatile memory cell, for storing at least one bit, on a semiconductor substrate, comprising on the substrate a trench, a first active area, a second active area, a channel region extending along a sidewall of the trench, the trench having a length extending in a first direction and a width extending in a second direction perpendicular thereto and the trench being covered on the sidewalls by a tunnel oxide and including at least one gate stack of a floating gate and a control gate, wherein the control gate extends to the bottom part of the trench, a first floating gate is located at a left trench wall to form a first stack with the control gate, and a second floating gate is located at a right trench wall to form a second stack with the control gate.

The present invention relates to a semiconductor device comprising a vertical split gate non-volatile memory cell for storing at least one bit as defined in the preamble of claim 1. Also, the present invention relates to an array comprising at least one such vertical split gate non-volatile memory cell. Moreover, the present invention relates to a method of fabrication of a semiconductor device comprising such a vertical split gate non-volatile memory cell.

From U.S. Pat. No. 6,087,222 a vertical split gate non-volatile memory cell is known which is an electrical erasable read-only memory cell (EEPROM). This EEPROM cell in accordance with the prior art comprises in a semiconductor substrate a trench which encompasses a gate structure consisting of a floating gate and a control gate on top of the floating gate. In this vertical non-volatile memory cell the floating gate is located at the bottom of the trench and the control gate is located as a via-like structure in the upper half of the trench. The control gate is separated from the floating gate by a dielectric layer. Source and drain regions are still arranged in a horizontal arrangement, with one region type located at a level close to the surface of the substrate adjacent to the trench and the other region type located below the bottom of the trench. In this arrangement the channel between source and drain is arranged, during use, in the vertical direction along the sidewall of the trench.

Due to the nature of the floating gate/control gate stack, in the EEPROM cell of U.S. Pat. No. 6,087,222 the electrical properties of the cell are affected by the relatively low capacitive coupling between the floating gate and the control gate.

Moreover, the method of U.S. Pat. No. 6,087,222 to form vertical split gate non-volatile memory cells with control gates as via-like structures may be rather complicated and, for that reason, may suffer from low production yields in newer device generations using 0.18 and 0.13 μm design rules.

It is an object of the present invention to provide a semiconductor device comprising a vertical non-volatile memory cell which has improved electrical properties relative to the EEPROM cell of the prior art.

The object is achieved by a semiconductor device comprising a vertical split gate non-volatile memory cell as defined in the preamble of claim 1, characterised in that the control gate extends to the bottom part of the trench, a first floating gate is located at a left side wall of the trench to form a first gate stack with the control gate, and a second floating gate is located at a right side wall of the trench to form a second gate stack with the control gate.

Also, the present invention relates to an array comprising at least one such non-volatile memory cell according to the present invention.

By providing an arrangement of a floating gate and control gate in a vertical split gate non-volatile memory cell according to the present invention, the electrical properties of the non-volatile memory cell are improved: a high coupling between floating gate and control gate is achieved.

A further object of the present invention is to provide a method for fabricating a semiconductor device comprising a vertical split gate non-volatile memory cell which is less complicated than the method of the prior art.

The present invention relates to a method for manufacturing the semiconductor device comprising the vertical split gate non-volatile memory cell according to the present invention.

The method as defined in the preamble of claim 5, is characterised in that the method comprises the following steps:

depositing poly-Si in the trench, the poly-Si having a planarised top surface;

forming isolation slits by a silicon dioxide in the trench for isolating the memory cell in the second direction by using a slit mask;

back-etching of the poly-Si;

back-etching of the silicon dioxide;

forming first spacers extending in the second direction on the planarised top surface of the poly-Si and second spacers extending in the first direction on the silicon dioxide;

etching of the poly-Si by a reactive ion etching process using the first spacers and the second spacers as a mask to form an etched recessed poly-Si portion serving as a floating gate, and an exposed bottom part of the trench;

forming the dielectric on the floating gate and the exposed bottom part of the trench;

depositing a second poly-Si layer over the dielectric;

planarising the second poly-Si used as the control gate extending from the top of the trench to the bottom of the trench covering the dielectric.

Such a method advantageously allows the structuring of the non-volatile memory cell according to the present invention for device generations using design rules for 0.18 μm technology and smaller.

Below, the invention will be explained with reference to some drawings, which are intended for illustration purposes only and not to limit the scope of protection as defined in the appended claims.

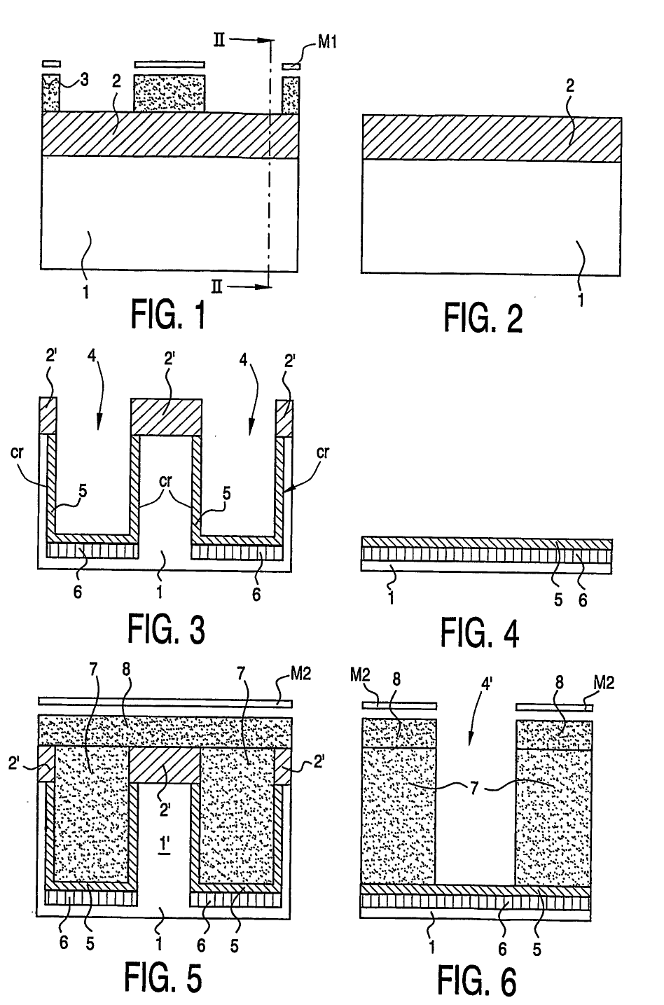

FIG. 1 shows a cross-sectional view in a first direction of a non-volatile memory cell according to the present invention in a first step;

FIG. 2 shows a cross-sectional view in a second direction of a non-volatile memory cell according to the present invention in a first step;

FIG. 3 shows a cross-sectional view in the first direction of a non-volatile memory cell according to the present invention in a second step;

FIG. 4 shows a cross-sectional view in the second direction of a non-volatile memory cell according to the present invention in a second step;

FIG. 5 shows a cross-sectional view in the first direction of a non-volatile memory cell according to the present invention in a third step;

FIG. 6 shows a cross-sectional view in the second direction of a non-volatile memory cell according to the present invention in a third step;

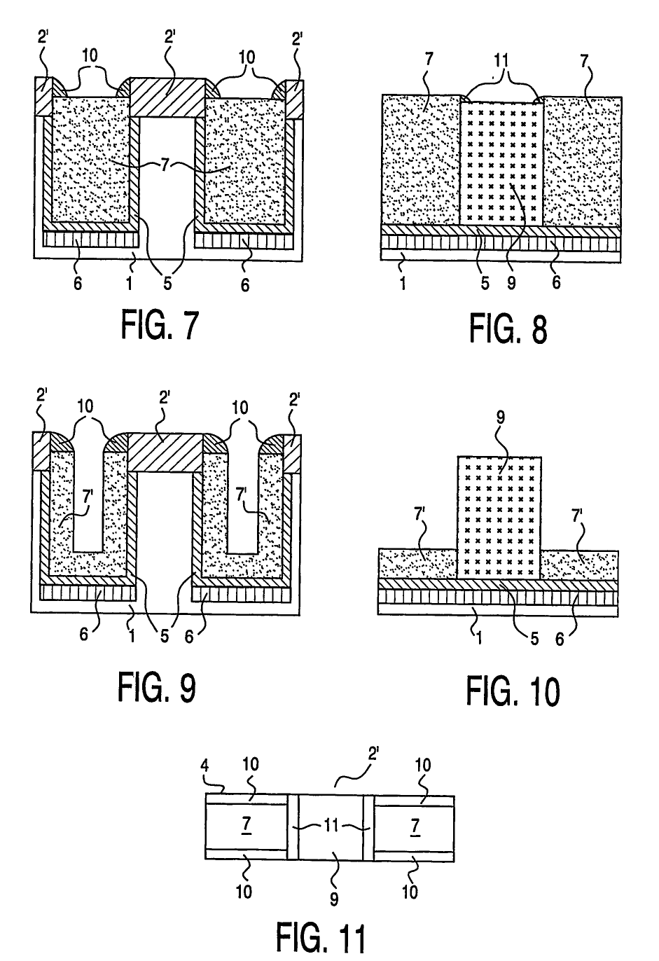

FIG. 7 shows a cross-sectional view in the first direction of a non-volatile memory cell according to the present invention in a fourth step;

FIG. 8 shows a cross-sectional view in the second direction of a non-volatile memory cell according to the present invention in a fourth step;

FIG. 9 shows a cross-sectional view in the first direction of a non-volatile memory cell according to the present invention in a fifth step;

FIG. 10 shows a cross-sectional view in the second direction of a non-volatile memory cell according to the present invention in a fifth step;

FIG. 11 shows a plane view of a non-volatile memory cell according to the present invention in the fifth step;

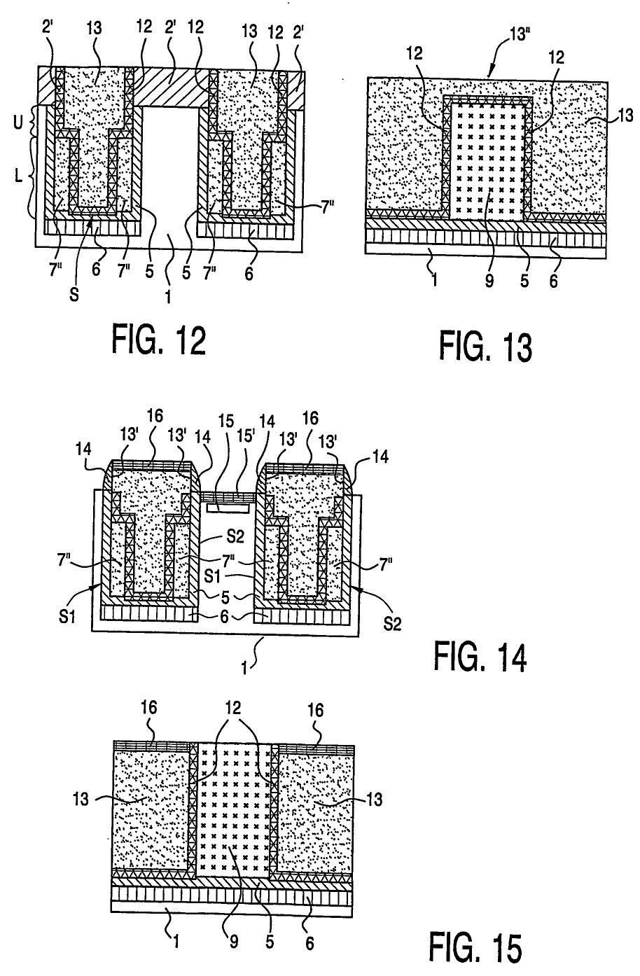

FIG. 12 shows a cross-sectional view in the first direction of a non-volatile memory cell according to the present invention in a sixth step;

FIG. 13 shows a cross-sectional view in the second direction of a non-volatile memory cell according to the present invention in a sixth step;

FIG. 14 shows a cross-sectional view in the first direction of a non-volatile memory cell according to the present invention in a first embodiment;

FIG. 15 shows a cross-sectional view in the second direction of a non-volatile memory cell according to the present invention in a first embodiment;

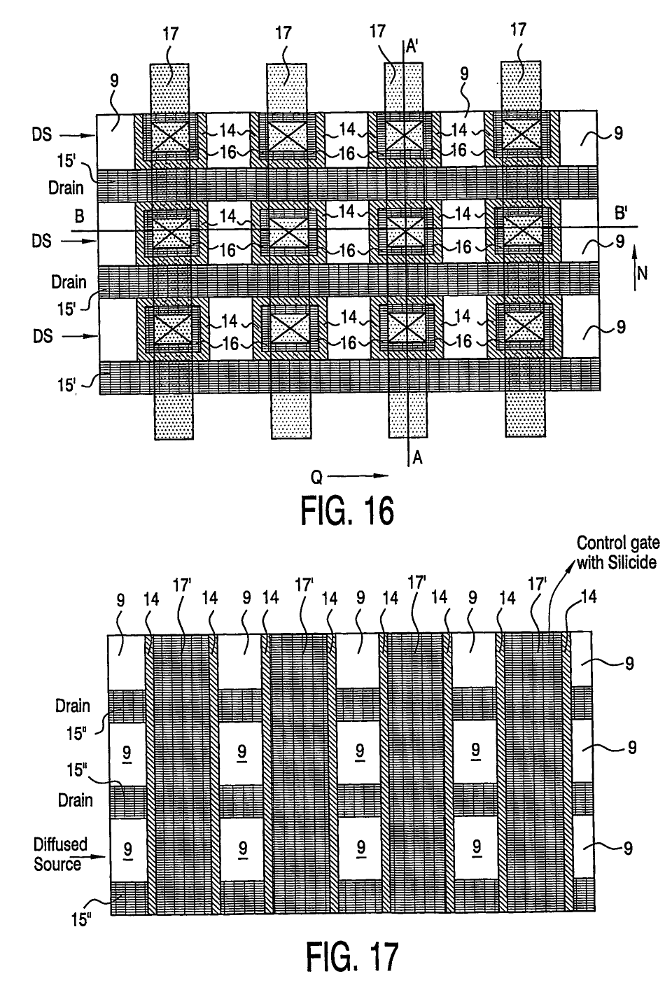

FIG. 16 shows a plane view of an array of non-volatile memory cells according to the present invention in a first embodiment;

FIG. 17 shows a plane view of an array of non-volatile memory cells according to the present invention in a second embodiment;

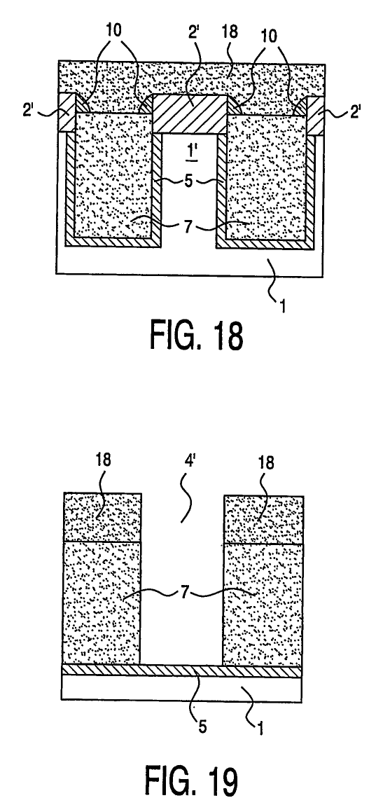

FIG. 18 shows a cross-sectional view in the first direction of a non-volatile memory cell according to the present invention in a first alternative step;

FIG. 19 shows a cross-sectional view in the second direction of a non-volatile memory cell according to the present invention in a first alternative step;

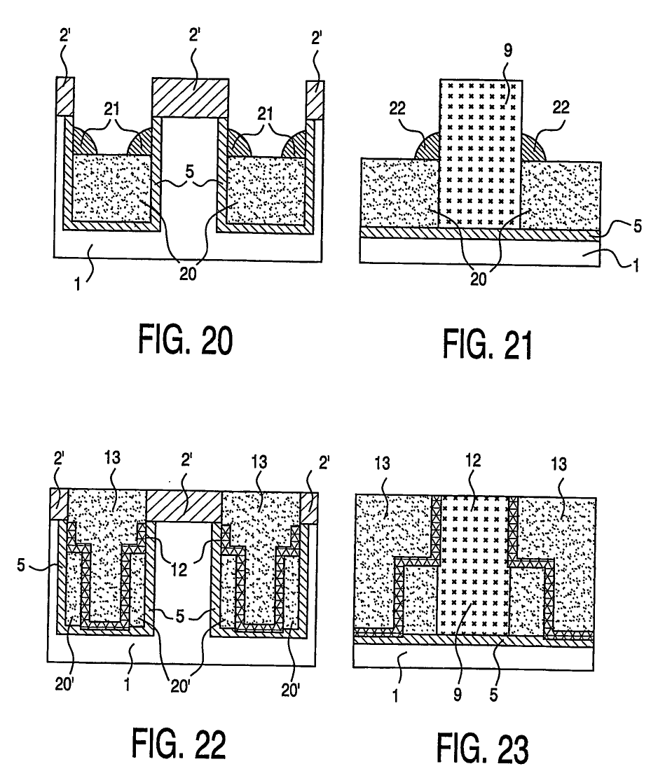

FIG. 20 shows a cross-sectional view in the first direction of a non-volatile memory cell according to the present invention in a third alternative step;

FIG. 21 shows a cross-sectional view in the second direction of a non-volatile memory cell according to the present invention in a third alternative step;

FIG. 22 shows a cross-sectional view in the first direction of a non-volatile memory cell according to the present invention in a fourth alternative step;

FIG. 23 shows a cross-sectional view in the second direction of a non-volatile memory cell according to the present invention in a fourth alternative step;

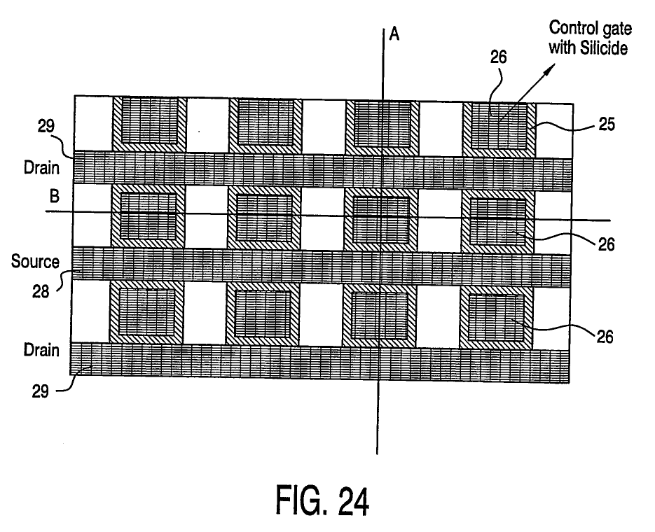

FIG. 24 shows a plane view of an array of non-volatile memory cells according to the present invention in a further embodiment.

Below, a vertical split gate non-volatile memory cell and a method for fabrication of such a vertical split gate non-volatile memory cell are described. Within this method, a number of alternative processing steps can be applied which result in a number of alternative embodiments of the vertical split gate non-volatile memory cell. First, a basic method for fabrication of a vertical split gate non-volatile memory cell according to the present invention and a first embodiment of such a vertical split gate non-volatile memory cell will be presented with reference to the drawings, which show consecutive steps during the fabrication of such a device. Processing steps are indicated by “PS” followed by a Roman numeral.

Next, each of the alternative processing steps will be described and the changes of the vertical split gate non-volatile memory cell with respect to the basic first embodiment of the vertical split gate non-volatile memory cell will be discussed.

However, it will be appreciated by persons skilled in the art that other alternative and equivalent embodiments of the invention can be conceived and reduced to practice without departing form the true spirit of the invention, the scope of the invention being limited only by the appended claims.

In the present invention, a vertical split gate non-volatile memory cell is described that comprises a trench structure that holds a split gate structure of a floating gate and a control gate as a memory cell. The vertical split gate non-volatile memory cell according to the present invention will have a high capacitive coupling between the floating gate and control gate and can be fabricated so as to be partly self-aligned. The use of a trench has the advantage of a small lateral size while in the vertical direction of the side wall of the trench still a long channel length can be maintained.

FIG. 1 shows a cross-sectional view in a first direction of a non-volatile memory cell according to the present invention in a first step. FIG. 2 shows a cross-sectional view in a second direction of a non-volatile memory cell according to the present invention in a first step. The first direction of FIG. 1 is perpendicular to the direction of the trench to be formed, while the second direction of FIG. 2 is parallel to it. The cross-section of FIG. 2 is indicated in FIG. 1 by the dashed line II-II. It is noted here that all cross-sections shown below are correlated in this manner.

On a semiconductor substrate 1, a silicon nitride layer 2 is deposited (process step PS-I). Possibly, first a thin oxide layer (not shown) may be formed before formation of the silicon nitride layer 2. Next, a resist layer 3 is applied on the silicon nitride layer 2 and patterned in a photolithographic step according to a first mask M1 (PS-II). First mask M1 is drawn schematically above the non-volatile memory cell structure.

Subsequently, the silicon nitride layer 2 is etched in step (PS-III) by reactive ion etching (RE), the patterned resist layer 3 being used as a mask to form trenches 4 in the substrate 1 within an intermediate substrate portion 1′ between adjacent trenches 4. The width of the trenches 4 can be chosen as the minimal feature size for the respective design rules. Typically, for 0.18 μm design rules the width of a trench 4 will be 400 nm.

FIG. 3 shows a cross-sectional view in the first direction of a non-volatile memory cell according to the present invention in a second step. FIG. 4 shows a cross-sectional view in the second direction of a non-volatile memory cell according to the present invention in a second step.

After stripping the patterned resist layer 3, a sacrificial oxide (not shown, PS-IV) is grown. An implantation step (PS-V) is performed to create channel implants (not shown) and threshold voltage (Vₜ) adjustment implants (not shown) along the sidewalls of the trench. The implantation step for channel and Vₜ adjustment should be at oblique incidence with the top surface of the substrate 1. Further, a high dose implantation step (with perpendicular angle of incidence, PS-VI) creates a line-shaped doped region 6 at the bottom of the trench and parallel to the trench, which will later act as a source region.

Next, the sacrificial oxide is removed by wet etching using HF dip, and a tunnel oxide 5 is grown thermally (PS-VII). The thickness of the tunnel oxide 5 is approx. 7 nm.

Scaling of the thickness of the oxide 5 relative to the lateral size of the memory cell is not relevant here, as it would be for a horizontal split-gate non-volatile memory cell, since the channel length in the vertical split gate non-volatile memory cell of the present invention will be determined by the depth of the trenches 4. In a horizontal split gate non-volatile memory cell the control gate length cannot be scaled down because the tunnel oxide 5 thickness cannot be scaled. A similar argument holds for the length of the floating gate.

Here, the cell (area) size of the vertical split gate non-volatile memory cell can be scaled down without scaling down the thickness of the tunnel oxide 5 and the length of the channel cr.

FIG. 5 shows a cross-sectional view in the first direction of a non-volatile memory cell according to the present invention in a third step.

FIG. 6 shows a cross-sectional view in the second direction of a non-volatile memory cell according to the present invention in a third step.

Trench 4 is filled with poly-silicon 7 by using a chemical vapour deposition (CVD) process in blanket mode (PS-VIII). Preferably, the poly-Si 7 is in-situ doped poly-Si, or the poly-Si should be doped in a separate step (possibly by implantation), to prevent gate depletion effects during use.

The poly-Si 7 is polished by a chemical mechanical polishing (CMP) process down to the top of the patterned silicon nitride layer 2′ which will act as a stopping layer for the CMP step (PS-IX).

After CMP, a second resist layer 8 is deposited and patterned by a mask M2 for etching slits 4′ in the poly-Si 7 (PS-X). Next, a RIE process is used to etch the slits 4′ (PS-XI). The slits 4′ run in a direction perpendicular to the direction of the trenches 4.

FIG. 7 shows a cross-sectional view in the first direction of a non-volatile memory cell according to the present invention in a fourth step.

FIG. 8 shows a cross-sectional view in the second direction of a non-volatile memory cell according to the present invention in a fourth step.

The patterned resist layer 8 is removed by a stripping process.

Next, an oxide (silicon dioxide) layer 9 is deposited by a e.g., TEOS (tetraethyl-ortho-silicate), HTO (high temperature oxide), or HDP (high density plasma) deposition process to fill the slits 4′ PS-XII).

The oxide layer 9 is planarised by CMP, using the patterned silicon nitride layer 2′ as a stopping layer (PS-XIII). The planarised oxide layer fills the slits 4′ in between the poly-Si 7 portions.

A partial back-etch of the poly-Si 7 portions is achieved by a RIE process to obtain a recessed poly-Si having a recess in its surface area slightly below the surface of the patterned silicon nitride layer 2′ (PS-XIV).

Also, the planarised oxide 9 is etched to obtain a recess that is somewhat deeper than the recessed poly-Si 7 portions (PS-XV).

In a subsequent step, spacers 10, 11 are formed to define a floating gate in each poly-Si 7 portion (PS-XVI).

The spacers can be made of a thin layer of deposited oxide (e.g., TEOS or HTO) and a layer of silicon nitride, or only an oxide layer, or an oxynitride layer. The choice of spacer material depends on the etch selectivity to the other materials in the structure. Note that, due to the slight difference in depth between the recessed poly-Si and the recessed planarised oxide, respectively, first spacers 10 formed on the recessed poly-Si 7 are larger than second spacers 11 formed on the recessed planarised oxide 9.

This will be explained in more detail below with reference to FIGS. 9 and 10.

FIG. 9 shows a cross-sectional view in the first direction of a non-volatile memory cell according to the present invention in a fifth step.

FIG. 10 shows a cross-sectional view in the second direction of a non-volatile memory cell according to the present invention in a fifth step.

The size of the first spacers 10 defines the thickness of the vertical floating gate to be formed: the first spacers 10 are used as a mask in a subsequent RIE process to etch a ‘groove’ in recessed poly-Si 7 portions. In the RIB process the first and second spacers 10, 11 will be removed by etching. Since the removal of the spacers 10, 11 will be slower than the removal of the poly-Si 7 due to the selectivity of the RIE process, the shape of the etched poly-Si portions to be formed can be controlled.

For a better understanding, the etch process can be considered as a three stage process: a first and a second step PS-XII) to form U-shaped poly-Si 7′ portions by using the spacers (10, 11) and a third step (PS-XIII) to form etched poly-Si portions 7″. In the first step XVII etching of poly-Si takes place, using the spacers 10, 11 as a ‘hard mask’. Due to the selectivity an initial groove in the poly-Si is etched to form U-shaped poly-Si 7′ portions (FIG. 9). Next, in the second step an RIB or wet etch process removes the spacers 10, 11. The final, third step PS-XIII creates the etched poly-Si portions 7″ by RM (see FIG. 12). (The initial groove shape created in the first step is etched until the bottom of the groove reaches the bottom of the trench 4.)

All poly-Si in the ‘groove’ will be removed by the etch. In each trench two separate poly-Si portions without any connection are formed: one etched poly-Si portion 7″ on the lower part L of the trench 4 at the left side and one etched poly-Si portion 7″ on the lower part L at the right-side (as shown in the cross-section of FIG. 12). In a later stage the two etched poly-Si portions 7″ will each form a floating gate. The height of the etched poly-Si portions 7″ remaining in trench 4 after etching depends on the actual processing parameters.

FIG. 11 shows a top view of a non-volatile memory cell according to the present invention in the fifth step in correspondence with the cross-section shown in FIG. 8.

It is noted that as shown in FIGS. 9, 10 and 11, the surface level of the floating gate poly-Si 7 needs to be below the surface level of the silicon nitride portion 2′ to facilitate the formation of first spacers 10. The surface level of the oxide 9 needs to be below the surface level of the poly-Si to allow formation of second spacers 11 on the oxide and not on the poly-Si. Obviously, the surface level of the oxide must be above the level of the channel region cr to allow formation of a control gate. In the poly-Si etching process just mentioned, the etching of poly-Si in a “cup”-shaped poly-Si portion would result in removal of the poly-Si only in the central bottom region of the “cup”. A connection between the portion 7″ on the left side and the portion 7″ on the right side would remain outside the central bottom region. In that case, the non-volatile memory cell would be a one-bit memory cell.

FIG. 12 shows a cross-sectional view in the first direction of a non-volatile memory cell according to the present invention in a sixth step.

FIG. 13 shows a cross-sectional view in the second direction of a non-volatile memory cell according to the present invention in a sixth step.

An interpoly dielectric layer 12 is deposited, which covers the exposed area U, L of the tunnel oxide 5 on the sidewalls and on the bottom S of the trench 4, the etched portions 7″, and the recessed planarised oxide 9 (PS-XIX).

The interpoly dielectric 12 may be a stacked layer of silicon dioxide-silicon nitride-silicon dioxide (an ONO layer), a silicon dioxide layer, an oxynitride layer, a high-k material, or any other suitable dielectric material.

Next, a chemical vapour deposition (CVD) process in blanket mode is used to deposit a second poly-Si for formation of the control gate 13 (PS-XX). Preferably, the second poly-Si is in-situ doped poly-Si, or in a separate step the second poly-Si should be doped (possibly by implantation) to prevent gate depletion effects during use.

The second poly-Si is polished by a second poly-Si CMP process up to the top of the patterned silicon nitride layer 2′ which will act as a stop layer for this CMP step (PS-XXI).

Optionally, before deposition of the interpoly dielectric 12, a HF dip may be applied to remove the exposed area of tunnel oxide 5 on the upper parts U of the side walls of the trench 4. In that case the interpoly dielectric 12 is deposited on the semiconductor material of the substrate 1: here the control gate 13 covers the exposed upper part portion of the channel region cr, only separated from the channel region cr by the interpoly dielectric layer 12.

It is noted that, as shown in FIG. 13, after the CMP step the control gates 13 in adjacent trenches 4 are still interconnected over the recessed planarised oxide 9 by a poly-Si connection 13″. A back-etch process is used to remove this poly-Si connection 13″ between adjacent control gates 13 (PS-XXII).

(Alternatively, the patterned silicon nitride layer 2′ could be removed before deposition of the second poly-Si layer by etching layer 2′ below the surface of the recessed planarised oxide 9. In this case, CMP is applied to form control gates 13 without a poly-Si connection 13″).

After formation of the separated control gates 13, the patterned silicon nitride layer 2′ is removed above the substrate portion 1′. Now the top of the control gate 13 encompasses free standing side walls 13′ towering over the substrate portion 1′ in between the trenches 4.

FIG. 14 shows a cross-sectional view in the first direction of a non-volatile memory cell according to the present invention in a first embodiment.

FIG. 15 shows a cross-sectional view in the second direction of a non-volatile memory cell according to the present invention in a first embodiment.

In the vertical split gate non-volatile memory cell according to the present invention, two gate stacks S1, S2 consisting of a floating gate 7″ and a control gate 13 exist. The floating gate 7″ is located along the lower part L of the side wall of the trench 4. The control gate 13 extends substantially from the top of the trench 4 to the bottom of the trench. In this configuration, the control gate 13 covers in the lower part of the trench the floating gate 7″ over its full working length and in the upper part U of the trench it covers the channel region directly over the length of the exposed side wall area.

Due to the separation of the floating gates 7″ in the trench on the left and the right sides, this embodiment comprises two cells per trench with the two gate stacks S1, S2 having a common control gate 13.

The transistor structures can now be finished by standard processing steps known to persons skilled in the art.

Third spacers 14 are formed on the free standing side wall portions 13′ of the control gate 13 (PS-XXIV).

Drain 15 is formed in the semiconductor substrate 1 between the third spacers 14 by implantation, e.g. by HDD (highly doped drain) implantation (PS-XXV).

Next, a silicide layer 16, possibly titanium disilicide or cobalt disilicide, is formed by a self-aligned silicidation process on top of the control gate 13 (PS-XXVI). At the same time, a silicide layer 15′ is formed on top of the drain area 15.

Further steps comprise back-end processes like metallisation (PS-XXVII) and passivation (PS-XXVIII).

In the vertical split gate non-volatile memory cell shown in FIG. 14 and 15 two floating gates 7″ are present in a trench 4, with a common control gate 13 in between the two floating gates 7″. The common control gate 13 will function for each of the floating gates 7″ as a control gate, as will be further explained with reference to the cell operation below. In this embodiment, the vertical split gate non-volatile memory cell is capable of storing two bits per memory cell.

FIG. 16 shows a plane view of an array of non-volatile memory cells according to the present invention in a first embodiment.

In the array of non-volatile memory cells according to the present invention, metal lines 17 for connecting the silicided areas 16 of the control gates 13 run in a first direction (A-A′). Silicided drain lines 15′ for connecting drains 15 run in a second direction (B-B′). Usually, the first and the second direction are perpendicular. Arrows DS mark the location and direction of the diffused source lines (not shown) that comprise sources 6.

Arrow N indicates the bit line number n of a position of a non-volatile memory cell in the array. Arrow Q indicates the column number q of a position of a non-volatile memory cell in the array.

For cell programming, source-side-injection (SSI) is used. For erasing, Fowler-Nordheim tunnelling is applied. In table 1 conditions for program, read and erase are given for the selected bitline n and for unselected lower (<n) and higher (>n) bitlines. The conditions are for selected odd bitlines (with n as bitline number). For selected even bitlines the conditions for unselected lower (<n) and higher (>n) bitlines should be interchanged. It is noted that the condition for erase affects a complete bitline or a sector of non-volatile memory cells.

Additionally, an erase operation may be performed by the source line (“source erasure”). A positive potential is applied to the source and a negative potential is applied to the gate. Advantageously, this may reduce the values of the needed potentials with respect to the value of a negative potential applied only to the gate.

TABLE 1
Conditions for program, read and erase for an array
of non-volatile memory cells as shown in FIG. 16.

| | Source | Drain | Control gate |
|---|---|---|---|
| Program | | | |
| Selected (odd n) | V_{cc} | 0 | Vₚ |
| Unselected (<n) | 0 | 0 | 0 |
| Unselected (>n) | V_{cc} | V_{cc} | 0 |
| Erase | | | |
| Line or sector | 0 | 0 | −Vₑ |
| Source erasure | Vₛ | 0 | −Vₑₛ |
| Read | | | |
| Selected (odd n) | Vᵣ | 0 | V_{rw} |
| Unselected (<n) | 0 | 0 | 0 |
| Unselected (>n) | Vᵣ | Vᵣ | 0 |
| Program | | | |
| Selected (even n) | V_{cc} | 0 | Vₚ |
| Unselected (<n) | V_{cc} | V_{cc} | 0 |
| Unselected (>n) | 0 | 0 | 0 |
| Erase | | | |
| Line or sector | 0 | 0 | −Vₑ |
| Source erasure | Vₛ | 0 | −Vₑₛ |
| Read | | | |
| Selected (even n) | Vᵣ | 0 | V_{rw} |
| Unselected (<n) | Vᵣ | Vᵣ | 0 |
| Unselected (>n) | 0 | 0 | 0 |

It is noted that Vₛ≦Vₑₛ, and Vₑₛ≦Vₑ, depending on the exact specifications of the memory cell.

In the first embodiment, as shown in FIG. 14, the non-volatile memory cell according to the present invention advantageously has a small lateral size, and it is possible to scale down the size of the cell. Also, the number of masks to define the vertical split gate non-volatile memory cell according to the present invention is low, viz. masks M1 and M2 as 10 discussed above. Moreover, due to the patterning of the floating gate 7″, a high capacitive coupling between floating gate 7″ and control gate 13 can be achieved. Furthermore, the channel length is independent of the lateral size of the non-volatile memory cell. Consequently, the thickness of the tunnel oxide 5 can remain at a value of approx. 7 nm, which is favourable with respect to the reliability of the cell structure.

Below, alternative embodiments of the method to fabricate a vertical split gate non-volatile memory cell according to the present invention are described. For each embodiment, the modification in the sequence of process steps will be explained. It is noted that for each alternative embodiment the basic sequence of the first embodiment, as described above, is used as reference. The sequence of process steps to form the first embodiment are listed in list 2. The individual modified process steps are listed in list 3.

FIG. 17 shows a plane view of an array of non-volatile memory cells according to the present invention in a second embodiment.

A slight disadvantage of the first embodiment of the non-volatile memory cell is the necessity to make a contact for each control gate 13 in the array and a metal line 17 running over it.

In the second embodiment, the contact scheme is simplified by implantation of drain lines (drains) 15″ before the definition of trenches 4 (in FIG. 1 and 2, PS-I-PS-VI), by using an extra masking step with a mask that is the inverse of trench mask M1 (PS-I^{a}).

This allows the formation of silicided control gate lines 17′ at the top level of the device to be built. The silicided control gate lines 17′ incorporate the silicided control gate area 16 (by process step PS-XXVI).

The formation of silicided control gate lines 17′ is achieved as follows: after the processing steps up to FIGS. 9 and 10 and before deposition of interpoly dielectric 12 (PS-XIX), the patterned silicon nitride layer 2′ is removed. Further processing is done as described with reference to the first embodiment.

It is noted that due to the absence of the patterned silicon nitride layer 2′ at this stage, the subsequent CMP step (PS-XXI) must be performed carefully.

FIG. 18 shows a cross-sectional view in the first direction of a non-volatile memory cell according to the present invention in a third embodiment.

FIG. 19 shows a cross-sectional view in the second direction of a non-volatile memory cell according to the present invention in a third embodiment.

A third embodiment of the non-volatile memory cell according to the present invention is obtained when the patterning step by the slit mask M2 (PS-X) is performed during a later processing stage.

In that case, after the CMP step of FIG. 5 and 6 (PS-IX), steps PS-X-PS-XIII are skipped and next, the poly-Si 7 is etched back (PS-XIV).

Then, the first spacers 10, running as lines in the first direction (A-A′), are formed (PS-XVI).

Next, alternative steps are performed (PS-XI^{a}, PS-XI-PS-XIII): A second resist 18 is applied and patterned using slit mask M2 (not shown, PS-XV^{a}). Then, poly-Si 7 and spacers 10 are etched by RIE (PS-XI).

In a further step, the resist 18 is stripped. Oxide is deposited by e.g., a TEOS, HDP or HTO process (PS-XII). The oxide layer (not shown) is deposited in the slit 4′ and on the surface area of the floating gates 7.

Subsequently, the oxide is planarised by CMP using the patterned silicon nitride layer 2′ as a stopping layer (PS-XM).

Now, the oxide over the surface of the floating gates 7 needs to be removed (PS-XIII^{a}): a photolithographic step is performed with an inverse slit mask M2′ to define the surface area of the floating gates 7. Next, the oxide over the floating gates is removed by etching, preferably by RIE.

The fabrication of the vertical split gate non-volatile memory cell in this third embodiment is continued by process steps PS-XVII-PS-XXVII as indicated in FIGS. 9, 10 and 11, 12 and 13, and 14 and 15.

It is noted that the application of the inverse slit mask M2′ in step PS-XIII^{a} may create a misalignment with the slit mask M2 used in a previous step.

In a fourth embodiment of the vertical split gate non-volatile memory cell according to the present invention, the patterning step by the slit mask M2 (PS-X) and reactive ion etching (PS-XI) is done at the end of the processing procedure. After formation (PS-VII) of the tunnel oxide 5, trench filling by poly Si (PS-XVIII) and CMP of poly-Si (PS-IX) are done followed by etching of poly-Si (PS-XVIII), deposition of interpoly dielectric (PS-XIX), and poly-Si CVD to form control gates (PS-XX).

Next, the stack of floating gate poly-Si, interpoly dielectric, and control gate poly-Si is patterned by the slit mask M2 (PS-XXI^{a}), followed by RIE (PS-XXI^{b}) to form the slit 4′.

In the RIE process three successive steps are carried out to define the separate non-volatile memory cells: first, etching of poly-Si 13, next, etching of interpoly dielectric 12 and finally, etching of poly-Si 7.

After this etching process (PS-XXI^{b}), a silicon dioxide is deposited in the slit 4′ by e.g., TEOS, HDP or HTO (step PS-XXI^{c}).

The silicon dioxide is planarised by CMP (PS-XXI^{d}) using the patterned silicon nitride layer 2′ as a stop layer.

The process continues with the removal of the silicon nitride 2′ (PS-XXII) and subsequent steps PS-XXV-PS-XXVIII.

In the process flow described according to the first embodiment, back-etching of the floating gate poly-Si 7 (PS-XIV) and of the planarised silicon dioxide 9 (PS-XV), which is performed in a single etching process sequence, is a critical step. The planarised silicon dioxide 9 should be etched to the same level or below that of the floating gate poly-Si 7. As explained above, the subsequent spacer formation (PS-XVI) on the floating gate poly-Si 7 (first spacers 10) and on the planarised oxide 9 (second spacers 11) is critical for etching a trench in the floating gate poly-Si 7 instead of a hole.

Also, back-etching of the control gate poly-Si 13 to a level below the planarised silicon dioxide 9, but still above the substrate level, is critical for the formation of third spacers 14 (PS-XXIV). Third spacers 14 are required here for drain implantation (PS-XXV) and silicidation of the control gate area (PS-XXVI).

In a fifth embodiment, processing is performed, as in the first embodiment, up to the process step of back-etching the floating gate poly-Si 7 (PS-XIV) and the planarised silicon dioxide 9 (PS-XV). The level of the planarised silicon dioxide 9 should be below the level of the floating gate poly-Si 7. Next, first spacers are formed (PS-XVI). Floating gate 7″ is defined by RIE (PS-XVII and PS-XVIII).

Subsequently, interpoly dielectric 12 and control gate poly-Si 13 are deposited (steps PS-XIX and PS-XX). In a following step interpoly dielectric 12 and control gate poly-Si 13 are planarised by CMP (PS-XXI).

Then, for the second time the patterning step by slit mask M2 (PS-XXII^{a}) is performed, followed by etching of poly-Si above the planarised silicon dioxide 9 (PS-XII^{b}). Directly after this step PS-XXII^{a}, a further silicon dioxide is deposited and planarised by a CMP step (PS-XXII^{c}). Further processing is performed as in the first embodiment using steps PS-XXIII-PS-XXVII.

In this alternative fifth embodiment, the critical step of the control gate poly-Si etch (PS-XIV) is omitted, although, unfortunately, an extra masking step and CMP step are necessary.

Also, in this alternative fifth embodiment, misalignment of the slit mask M2 in its two applications (PS-X and PS-XXII^{a}) is not critical, since there is no risk of forming poly-Si stringers.

In an alternative sixth embodiment, the step of source implantation (PS-I^{b}) is carried out before the definition and processing of the trenches 4 (PS-I-PS-III). Here an implantation mask M0 is necessary to create implanted source lines (M0 corresponds substantially with trench mask M1). The implantation process should be performed with sufficiently high energy and a sufficiently high dose to obtain source lines buried at suitable depth in the substrate 1. It is noted here that source implantation may also be done at a shallow depth in the substrate 1. In the latter case, an epitaxial layer of silicon must be grown before deposition of the silicon nitride layer 2 (and successive process steps). The depth of the epitaxial layer must be sufficient to form trenches 4 of sufficient height.

Next, processing can be performed as indicated in the first embodiment.

Advantageously, the source lines can be created in the second direction (B-B′, see FIG. 16) perpendicular to the longitudinal direction of the trenches, which simplifies the layout of the vertical split gate non-volatile memory cell: the control gate lines 17 or 17′ may now run in the longitudinal direction (A-A′) of the trenches. Accordingly, back-etching of the control gate poly-Si connections 13′ (PS-XXII) can now be omitted. Preferably, in the sixth embodiment, the drain lines 15; 15′; 15″ run parallel to the control gate lines 17; 17′.

Programming and erasing of an array of vertical split gate non-volatile memory cells according to this embodiment can be done by the mechanism of source side injection and Fowler-Nordheim tunnelling, respectively, as will be known to persons skilled in the art.

FIG. 20 shows a cross-sectional view in the first direction of a non-volatile memory cell according to the present invention in an alternative step wherein floating gate material is back-etched.

FIG. 21 shows a cross-sectional view in the second direction of a non-volatile memory cell according to the present invention in this alternative step.

In a further embodiment, a vertical split gate non-volatile memory cell is fabricated which comprises one bit per cell. The processing procedure of such a vertical non-volatile memory cell is as follows:

Trenches 4 are defined and formed in substrate 1 by process steps PS-I-PS-III. Next, sacrificial oxide is deposited on the sidewalls of the trenches 4 (PS-IV) followed by channel implantation (PS-V). No source implantation is done here.

Then, poly-Si 7 is grown in trenches 4 (PS-VIII), followed by CMP of the poly-Si 7 (PS-IX).

Further, slits 4′ are formed by steps PS-X-PS-XIII. After the back-etch the etched poly-Si portion 20 should cover a substantial part of the trench, typically about half of the trench height. In a following spacer formation process PS-XV^{a}, fourth spacers 21, 22 are formed on the etched poly-Si portion 20, adjacent to the side walls i.e., the tunnel oxide 5 and adjacent to the silicon dioxide 9 deposited in slit 4′, respectively. The fourth spacers 21, 22 can be made of a small layer of deposited oxide (e.g., TEOS, HTO, or HDP) and a layer of silicon nitride, or of silicon dioxide only, or oxynitride. The actual choice depends on etch selectivity to the materials already deposited.

In a further process step (step PS-XVIII) the etched poly-Si portion 20 is etched by RIE using the fourth spacers 21, 22 as masks. A hole is etched in the etched poly-Si portion 20 down to the bottom tunnel oxide 5, thus forming a floating gate portion 20′.

An interpoly dielectric layer 12 is deposited, which covers the exposed area of the tunnel oxide 5 on the sidewalls, the remainder of fourth spacers 21, 22, the bottom of the trench 4, the exposed floating gate portions 20′ in the groove, and the recessed planarised oxide 9 (PS-XIX). The interpoly dielectric 12 may be a stacked layer of silicon dioxide-silicon nitride-silicon dioxide (an ONO layer), a silicon dioxide layer, an oxynitride layer, a high-k material, or any other suitable dielectric material.

Then, a poly-Si CVD process in blanket mode is used to deposit poly-Si to form the control gate (PS-XX) on the interpoly dielectric 12. Preferably, the poly-Si for the control gate 13 is in-situ doped poly-Si, or in a separate step the second poly-Si should be doped (possibly by implantation).

The poly-Si for the control gate 13 is polished by a CMP process for poly-Si (PS-XXI^{a}) as far as the top of the patterned silicon nitride layer 2′ which acts as a stopping layer.

FIG. 22 shows a cross-sectional view in the first direction of a non-volatile memory cell according to the present invention after process step PS-XXI.

FIG. 23 shows a cross-sectional view in the second direction of a non-volatile memory cell according to the present invention after process step PS-XXI.

Next, the patterned silicon nitride layer 2′ is removed (PS-)0I. The vertical non-volatile memory cell is finished by standard processing: spacer formation (PS-XIV), active area implantation (PS-XXV), silicidation (PS-XXVI), and metallisation and passivation (PS-XXVII, PS-XXVIII).

FIG. 24 shows a plane view of an array of non-volatile memory cells according to the present invention in this further embodiment.

The spacer formation process (PS-XXIII) creates fifth spacers (25). The active area implantation process (PS-XXIV) creates both source and drain contacts (not shown) of the vertical non-volatile memory cell. By silicidation, silicided source lines 28 and silicided drain lines 29 are formed. The control gate lines (not shown) running perpendicularly to the direction of the source and drain lines 28, 29 can be implemented as metal lines 17 as described in the first embodiment or as silicided lines 17′ as described in the second embodiment of the present invention.

Due to the etching (PS-XVIII) using the mask formed by fourth spacers 21, 22, the floating gate portion 20′ covers both the sidewalls of tunnel oxide 5 and it covers the oxide 9 deposited in slit 4′ on all sides and forms a single floating gate. The vertical split gate non-volatile memory cell in this embodiment will hold only one bit per memory cell.

Although the bit density of the vertical split gate non-volatile memory cell in the last embodiment is only half the density of the vertical split gate non-volatile memory cell of the other embodiments, advantageously, a higher coupling between floating gate and control gate can be achieved in this last embodiment. Furthermore, lower voltages can be applied for the operation of the vertical split gate non-volatile memory cell of the last embodiment. Also, the step of source implantation in the bottom of the trench 4 may be omitted: the processing of this non-volatile memory cell is simpler as compared to the non-volatile memory cells according to the previous embodiments.

List 1. Reference list

| 1. | Semiconductor substrate | 1′. Substrate portion in between | |
|---|---|---|---|
| | | adjacent trenches | |
| 2. | Silicon nitride | 2′ Patterned silk on nitride | |
| 3. | Resist 1 | | |
| 4. | Trench | 4′ Slit | |
| 5. | Tunnel oxide | | |
| 6. | Source | | |
| 7. | Floating gate | 7′ Etched floating | 7″ Floating |
| | | gate | gate blocks |
| 8. | Second resist | | |
| 9. | Silicon dioxide | | |
| 10. | First spacer | | |
| 11. | Second spacer | | |
| 12. | Interpoly dielectric | | |
| 13. | Control gate (CG) poly | 13′ CG free | 13″ Poly-Si |
| | | standing wall | connection |
| 14. | Third spacer | | |
| 15. | Drain | 15′ Silicided | 15″ Implanted |
| | | drain (line) | drain line |
| 16. | Silicide | | |
| 17. | Metal line | 17′ Silicided | |
| | | control gate line | |
| 18. | Third resist | | |
| 19. | Etched floating gate | 19′ Conformal | 19″ Poly-Si |
| | | poly-Si layer | spacer |
| 20. | Etched poly-Si portion | 20′ Floating | |
| | | gate portion | |
| 21. | Fourth spacer | | |
| 22. | Fourth spacer | | |
| 25. | Spacer | | |
| 26. | Silicided control gate | | |
| 28. | Silicided source line | | |
| 29. | Silicided drain line | | |

| | |
|---|---|
| S | Bottom part of trench |
| CR | Channel region |
| DS | Diffused source line |
| L | Lower part of trench side wall |
| M0 | Implantation mask |
| M1 | Trench mask |
| M2 | Slit mask |
| SL | Source line |
| U | Upper part of trench side wall. |

List 2. List of process steps

| | |
|---|---|
| PS-1. | Deposition of silicon nitride layer |
| PS-II. | Patterning by mask M1 |
| PS-III. | RIE of silicon nitride and substrate (trenches) |
| PS-IV. | Growth of sacrificial oxide |
| PS-V. | Channel implantation |
| PS-VI. | Source implantation |
| PS-VII. | Growth of tunnel oxide |
| PS-VIII. | Trench fill poly-Si |
| PS-IX. | CMP of poly-Si |
| PS-X. | Patterning by mask M2 |
| PS-XI. | Slit etching by RIE |
| PS-XII. | Growth of oxide layer: TEOS, etc. |
| PS-XIII. | CMP of oxide |
| PS-XIV. | Back-etch of poly-Si |
| PS-XV. | Back-etch of planarised oxide |
| PS-XVI. | Spacer formation |
| PS-XVII. | Initial ‘Groove’ etching by poly-Si RIE |
| PS-XVIII. | Further etching by poly-Si RIE to bottom oxide |
| PS-XIX. | Deposition of interpoly dielectric |
| PS-XX. | Poly-Si CVD |
| PS-XXI. | Second CMP of poly-Si |
| PS-XXII. | Back-etching of poly-Si connections 13′ |
| PS-XXIII. | Removal of patterned silicon nitride 2′ |
| PS-XXIV. | Spacer formation |
| PS-XXV. | Drain implantation |
| PS-XXVI. | Silicidation of control gate and drain |
| PS-XXVII. | Metallisation |
| PS-XXVIII. | Passivation |

List 3. List of alternative process steps

| | |
|---|---|
| PS-I^{a} | Inverse slit mask M1′ |
| PS-I^{b} | Implantation of source lines, by mask M0 |
| PS-III^{a} | Implantation of drain lines, before III |
| PS-XI^{a} | Patterning by slit mask M2 |
| PS-XIII^{a} | Removal of silicon dioxide over floating gates |
| PS-XIV^{a} | Patterning by slit mask M2 |
| PS-XV^{a} | Spacer formation |
| PS-XVIII^{a} | Formation of silicided control gate, before XVIII |
| PS-XXI^{a} | Patterning by slit mask M2 |
| PS-XXI^{b} | Reactive Ion etching to form slit 4′ |
| PS-XXI^{c} | Growth of oxide in slit 4′ |
| PS-XXI^{d} | Planarisation of oxide by CMP |
| PS-XXII^{a} | Second application of slit mask M2 |
| PS-XXII^{b} | Etching of poly-Si above the planarised silicon dioxide 9 |
| PS-XXII^{c} | Deposition of silicon dioxide and planarisation by CMP |

1. Semiconductor device comprising
a vertical split gate non-volatile memory cell, for storing at least one bit, on a semiconductor substrate, comprising on said substrate
a trench,
a first active area,
a second active area,
a channel region extending substantially along a side wall of said trench,
said trench having a length in a first direction and a width in a second direction, said first direction being perpendicular to said second direction,
said trench being covered on said side walls by a tunnel oxide and comprising at least one gate stack,
said gate stack consisting of a floating gate and a control gate,
said floating gate being separated from said control gate by a dielectric, characterised in that said control gate extends to the bottom part of said trench,
a first floating gate is located at a left side wall of said trench to form a first gate stack with said control gate, and a second floating gate is located at a right side wall of said trench to form a second gate stack with said control gate.

2. Semiconductor device according to claim 1, characterised in that said dielectric extends along an upper exposed part of said side wall of said trench; and said control gate extends along said dielectric covering said upper exposed part of said side wall of said trench.

3. Semiconductor device, according to claim 1, characterised in that said first floating gate and said second floating gate are interconnected by an interconnecting poly-Si portion.

4. Semiconductor device according to claim 1, characterised in that said first floating gate and said second floating gate are isolated from each other.

5. Method for fabrication of a semiconductor device comprising a vertical split gate non-volatile memory cell, according to claim 1, characterised in that said method comprises:
depositing poly-Si in said trench, said poly-Si having a planarised top surface;
forming isolation slits by a silicon dioxide in said trench for isolating said memory cell in said second direction by using a slit mask;
back-etching of said poly-Si;
back-etching of said silicon dioxide;
forming first spacers extending in said second direction on said planarised top surface of said poly-Si and second spacers extending in said first direction on said silicon dioxide;
etching of said poly-Si by a reactive ion etching process using said first spacers and said second spacers as a mask to form an etched recessed poly-Si portion serving as a floating gate, and a lower exposed part of said trench;
forming said dielectric on said floating gate and said lower exposed part of said trench;
depositing a second poly-Si layer over said dielectric;
planarising said second poly-Si used as said control gate extending from the top of said trench to the bottom of said trench covers said dielectric.

6. Method for fabrication of a semiconductor device according to claim 5, characterised in that said method further comprises:
the formation of an upper exposed part (U) of said side wall of said trench (4);
the formation of said dielectric on said upper exposed part of said side wall of said trench.

7. Method for fabrication of a semiconductor device according to claim 5 or 6, according to claim 5, characterised in that said method further comprises:
forming further spacers adjacent to said control gate on said top surface;
implantation of said second active area;
silicidation of said control gate and said drain;
creation of conductive connections to said control gate.

8. Method for fabrication of a semiconductor device according to claim 7, characterised in that
said poly-Si has a silicon surface level,
said silicon dioxide has an oxide surface level, and
said silicon nitride has a nitride surface level, said silicon surface level being arranged below said nitride surface level, said oxide surface level being arranged below said silicon surface level and above said channel region to allow formation of said second spacers on said silicon oxide without formation on said poly-Si.

9. Method for fabrication of a semiconductor device according to claim 7, characterised in that
said poly-Si has a silicon surface level,
said silicon dioxide has an oxide surface level, and
said silicon nitride has a nitride surface level, said silicon surface level being arranged substantially equal to said nitride surface level, said oxide surface level being arranged substantially equal to said silicon surface level and said channel region to allow simultaneous formation of said first spacers on said poly-Si and said second spacers on said silicon oxide, said first and second spacers having substantially equal thickness and height.

10. Method for fabrication of a semiconductor device according to claim 3, characterised in that said method comprises:
depositing poly-Si in said trench, said poly-Si having a top surface;
forming isolation slits by a silicon dioxide in said trench for isolating said memory cell in said second direction by using a slit mask;
forming first spacers extending in said second direction and second spacers extending in said first direction on said top surface of said poly-Si;
etching of said poly-Si by a reactive ion etching process using said first spacers and second spacers as a mask to form an etched recessed poly-Si portion serving as a floating gate, and a lower exposed part of said trench;
forming said dielectric on said floating gate and said lower exposed part of said trench;
depositing a second poly-Si layer over said dielectric;
planarising said second poly-Si used as said control gate extending from the top of said trench to the bottom of said trench covers said dielectric;
a second patterning by means of said slit mask;
reactive ion etching of poly-Si over said silicon dioxide;
depositing of a further silicon dioxide in blanket mode and planarising said further silicon dioxide.

11. Method for fabrication of a semiconductor device according claim 3, characterised in that said method comprises:
depositing poly-Si in said trench, said poly-Si having a top surface;
forming isolation slits by a silicon dioxide in said trench for isolating said memory cell in said second direction by using a slit mask;
a second application of said slit mask;
back-etching of said poly-Si;
back-etching of said silicon dioxide;
forming said first spacers extending in said first direction on said top surface of said poly-Si;
etching of said poly-Si by a reactive ion etching process using said first spacers and said second spacers as a mask to form an etched recessed poly-Si portion serving as a floating gate and a lower exposed part of said trench;
forming said dielectric on said floating gate and said lower exposed part of said trench;
depositing a second poly-Si layer over said dielectric;
planarising said second poly-Si used as said control gate extending from the top of said trench to the bottom of said trench covers said dielectric.

12. Method for fabrication of a semiconductor device according to claim 5, characterised in that said method further comprises:
as an initial process the implantation of said first active area using an implantation mask substantially corresponding to said trench mask.

13. Method for fabrication of a semiconductor device according to claim 5, characterised in that said creation of conductive connections relates to the creation of metal lines.

14. Method for fabrication of a semiconductor device according to claim 5, characterised in that said creation of conductive connections relates to the creation of silicided control gate lines and silicided drain lines.

15. Array of memory cells comprising at least one vertical split gate non-volatile memory cell according to claim 1.

16. Array of memory cells comprising at least one vertical split gate non-volatile memory cell according to claim 2.

17. Array of memory cells comprising at least one vertical split gate non-volatile memory cell according to claim 3.

18. Array of memory cells comprising at least one vertical split gate non-volatile memory cell according to claim 4.
